(19) United States
(12) Patent Application Publication
(10) Pub. No.: US 2025/0293188 A1
(43) Pub. Date: Sep. 18, 2025

(54) MANAGING PERIPHERAL CIRCUITRIES IN SEMICONDUCTOR DEVICES

(71) Applicant: Yangtze Memory Technologies Co., Ltd., Wuhan (CN)

(72) Inventors: Danyang WEI, Wuhan (CN); Zongliang HUO, Wuhan (CN); Yanhong WANG, Wuhan (CN); Liang CHEN, Wuhan (CN); Zichen LIU, Wuhan (CN); Wei LIU, Wuhan (CN); Zhichao DU, Wuhan (CN)

(21) Appl. No.: 18/767,944

(22) Filed: Jul. 9, 2024

Related U.S. Application Data
(63) Continuation of application No. PCT/CN2024/081206, filed on Mar. 12, 2024.

(51) Int. Cl. H01L 23/00; H01L 23/48; H10B 12/00; H10B 80/00

(52) U.S. Cl. CPC H01L 24/08; H01L 23/481; H01L 24/80; H10B 12/30; H10B 80/00; H01L 2224/08145; H01L 2224/80895; H01L 2224/80896

(57) ABSTRACT

Systems, devices, and formation methods for a semiconductor device are provided. In one aspect, a semiconductor device includes semiconductor structures and at least one control structure. Each of the semiconductor structures includes a memory array and a first circuitry coupled to the memory array. The control structure includes second circuitries for the semiconductor structures. Each of the second circuitries is coupled to a memory array of a respective semiconductor structure of the semiconductor structures. The semiconductor structures and the at least one control structure are stacked together along a direction.

### CROSS-REFERENCE TO RELATED APPLICATIONS

This application is a continuation of International Application No. PCT/CN2024/081206, filed on Mar. 12, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory DRAMs. The semiconductor memory devices can have various structures to increase a density of memory cells and lines on a chip. A memory device normally includes a memory array of memory cells and control circuitries for facilitating operations of the memory array.

### SUMMARY

The present disclosure describes methods, devices, systems and techniques for managing three-dimensional (3D) semiconductor devices.

One aspect of the present disclosure features a semiconductor device, including semiconductor structures and at least one control structure. Each of the semiconductor structures includes a memory array and a first circuitry coupled to the memory array. At least one control structure includes second circuitries for the semiconductor structures. Each of the second circuitries is coupled to a memory array of a respective semiconductor structure of the semiconductor structures. The semiconductor structures and the at least one control structure are stacked together along a direction.

In some implementations, the at least one control structure includes two or more control structures that are connected together to an external device.

In some implementations, the semiconductor structures include a first semiconductor structure having a first bonding layer and a second semiconductor structure having a second bonding layer. The at least one control structure includes a control structure having a third bonding layer and a fourth bonding layer. The third bonding layer is in a first side of the control structure. The fourth bonding layer is in a second side of the control structure that is opposite to the first side of the control structure along the direction. The first semiconductor structure and the second semiconductor structure are integrated on opposite sides of the control structure. The first bonding layer is in contact with the third bonding layer and the second bonding layer is in contact with the fourth bonding layer.

In some implementations, a first circuitry of the first semiconductor structure and the first bonding layer are in a first side of the first semiconductor structure. A first circuitry of the second semiconductor structure and the second bonding layer are in a first side of the second semiconductor structure. The control structure includes a first peripheral circuitry and a second peripheral circuitry in the first side of the control structure. The first peripheral circuitry is connected to a first memory array of the first semiconductor structure. The second peripheral circuitry is connected to a second memory array of the second semiconductor structure.

In some implementations, the semiconductor device includes a first conductive interconnection structure on the second side of the control structure. The first peripheral circuitry and the second peripheral circuitry are respectively connected to the first conductive interconnection structure. The semiconductor device further includes a second conductive interconnection structure on a second side of the second semiconductor structure that is opposite to the first side of the second semiconductor structure along the direction. The first circuitry of the first semiconductor structure is connected to the first peripheral circuitry at least by a first conductive structure coupled between the first circuitry of the first semiconductor structure and the first conductive interconnection structure. The first conductive structure extends through the first bonding layer, the third bonding layer, and the control structure along the direction. The first circuitry of the second semiconductor structure is connected to the second peripheral circuitry at least by a second conductive structure coupled between the first circuitry of the second semiconductor structure and the second conductive interconnection structure and a third conductive structure coupled between the second conductive interconnection structure and the first conductive interconnection structure. The second conductive structure extends at least partially through the second semiconductor structure along the direction. The third conductive structure extends through the second semiconductor structure, the second bonding layer, and the fourth bonding layer along the direction.

In some implementations, the first bonding layer includes one or more first conductive contacts isolated by a first dielectric material. The second bonding layer includes one or more second conductive contacts isolated by a second dielectric material. The third bonding layer includes one or more third conductive contacts isolated by a third dielectric material. The fourth bonding layer includes one or more fourth conductive contacts isolated by a fourth dielectric material. At least one of the one or more first conductive contacts is in contact with a corresponding one of the one or more third conductive contacts, and at least one of the one or more second conductive contacts is in contact with a corresponding one of the one or more fourth conductive contacts.

In some implementations, the semiconductor device includes a conductive interconnection structure on a second side of the first semiconductor structure that is opposite to the first side of the first semiconductor structure along the direction. The first peripheral circuitry is connected to the conductive interconnection structure by a first conductive structure extending in the first semiconductor structure, a first conductive contact of the one or more first conductive contacts, and a corresponding third conductive contact of the one or more third conductive contacts that is in contact with the first conductive contact. The first circuitry of the first semiconductor structure is connected to the first peripheral circuitry by one or more other first conductive contacts being in contact with corresponding one or more other third conductive contacts. The first circuitry of the second semiconductor structure is connected to the second peripheral circuitry by the at least one of the one or more second conductive contacts, the corresponding one of the one or more fourth conductive contacts, and a second conductive structure at least partially extending through the control structure.

In some implementations, the at least one control structure includes a first control structure having a first bonding layer. The semiconductor structures include a first semiconductor structure and a second semiconductor structure that are stacked on a first side of the first control structure along the direction. The first semiconductor structure includes a second bonding layer in a first side of the first semiconductor structure and a third bonding layer in a second side of the first semiconductor structure that is opposite to the first side of the first semiconductor structure. The second semiconductor structure includes a fourth bonding layer. The first semiconductor structure is stacked on the first control structure with the first bonding layer being in contact with the second bonding layer. The second semiconductor structure is stacked on the first semiconductor structure with the fourth bonding layer being in contact with the third bonding layer.

In some implementations, a first circuitry of the first semiconductor structure and the second bonding layer are in the first side of the first semiconductor structure. A first circuitry of the second semiconductor structure and the fourth bonding layer are in a first side of the second semiconductor structure. The first control structure includes a first peripheral circuitry and a second peripheral circuitry in the first side of the first control structure. The first peripheral circuitry is connected to a first memory array of the first semiconductor structure. The second peripheral circuitry is connected to a second memory array of the second semiconductor structure.

In some implementations, the semiconductor device includes a first conductive interconnection structure on the second side of the first semiconductor structure. The first conductive interconnection structure is connected to the first circuitry of the first semiconductor structure. The semiconductor device further includes a second conductive interconnection structure on a second side of the second semiconductor structure that is opposite to the first side of the second semiconductor structure along the direction. The second conductive interconnection structure is connected to the first circuitry of the second semiconductor structure. The first circuitry of the first semiconductor structure is connected to the first peripheral circuitry at least by a first conductive structure coupled between the first conductive interconnection structure and the first peripheral circuitry. The first conductive structure extends at least partially through the first semiconductor structure along the direction. The first circuitry of the second semiconductor structure is connected to the second peripheral circuitry at least by a second conductive structure coupled between the second conductive interconnection structure and the second peripheral circuitry. The second conductive structure extends through at least partially through the second semiconductor structure and at least partially through the first semiconductor structure along the direction.

In some implementations, the at least one control structure includes a second control structure. The semiconductor structures include a first plurality of semiconductor structures including the first semiconductor structure and the second semiconductor structure and a second plurality of semiconductor structures. The first plurality of semiconductor structures are stacked on the first side of the first control structure. The first plurality of semiconductor structures and the second semiconductor structures are stacked on opposite sides of the second control structure along the direction.

In some implementations, the first control structure includes a first plurality of second circuitries respectively coupled to first circuitries in the first plurality of semiconductor structures. The second control structure includes a second plurality of second circuitries respectively coupled to first circuitries in the second plurality of semiconductor structures.

In some implementations, a memory cell of the memory array includes a transistor and a capacitor. The transistor includes a gate as at least part of a word line, a first terminal coupled to a bit line, and a second terminal coupled to the capacitor. The bit line and the capacitor are on a same side of the word line.

In some implementations, the first circuitry includes at least one of a sense amplifier coupled to a corresponding bit line or a word line driver coupled to a corresponding word line. The second circuitry includes an input-output (I/O) circuitry configured to communicate with one or more external devices.

Another aspect of the present disclosure features a semiconductor device, including semiconductor structures and at least one control structure. Each of the semiconductor structures includes a memory array and a first circuitry coupled to the memory array. The at least one control structure includes second circuitries for the semiconductor structures. The semiconductor structures and the at least one control structure are stacked together along a direction. A memory cell of the memory array includes a transistor and a capacitor. The transistor includes a gate as at least part of a word line, a first terminal coupled to a bit line, and a second terminal coupled to the capacitor. The bit line and the capacitor are on a same side of the word line.

In some implementations, the semiconductor structures include a first semiconductor structure having a first bonding layer and a second semiconductor structure having a second bonding layer. The at least one control structure includes a control structure having a third bonding layer and a fourth bonding layer. The third bonding layer is in a first side of the control structure. The fourth bonding layer is in a second side of the control structure that is opposite to the first side of the control structure along the direction. The first semiconductor structure and the second semiconductor structure are integrated on opposite sides of the control structure. The first bonding layer is in contact with the third bonding layer and the second bonding layer is in contact with the fourth bonding layer. A first circuitry of the first semiconductor structure and the first bonding layer are in a first side of the first semiconductor structure. A first circuitry of the second semiconductor structure and the second bonding layer are in a first side of the second semiconductor structure. The control structure includes a first peripheral circuitry and a second peripheral circuitry in the first side of the control structure. The first peripheral circuitry is connected to a first memory array of the first semiconductor structure and the second peripheral circuitry is connected to a second memory array of the second semiconductor structure.

In some implementations, the first bonding layer includes one or more first conductive contacts isolated by a first dielectric material. The second bonding layer includes one or more second conductive contacts isolated by a second dielectric material. The third bonding layer includes one or more third conductive contacts isolated by a third dielectric material. The fourth bonding layer includes one or more fourth conductive contacts isolated by a fourth dielectric material. At least one of the one or more first conductive contacts is in contact with a corresponding one of the one or more third conductive contacts. At least one of the one or more second conductive contacts is in contact with a corresponding one of the one or more fourth conductive contacts.

In some implementations, the at least one control structure includes a first control structure having a first bonding layer. The semiconductor structures include a first semiconductor structure and a second semiconductor structure that are stacked on a first side of the first control structure along the direction. The first semiconductor structure includes a second bonding layer in a first side of the first semiconductor structure and a third bonding layer in a second side of the first semiconductor structure that is opposite to the first side of the first semiconductor structure. The second semiconductor structure includes a fourth bonding layer. The first semiconductor structure is stacked on the first control structure with the first bonding layer being in contact with the second bonding layer. The second semiconductor structure is stacked on the first semiconductor structure with the fourth bonding layer being in contact with the third bonding layer. A first circuitry of the first semiconductor structure and the second bonding layer are in the first side of the first semiconductor structure. A first circuitry of the second semiconductor structure and the fourth bonding layer are in a first side of the second semiconductor structure. The first control structure includes a first peripheral circuitry and a second peripheral circuitry in the first side of the first control structure. The first peripheral circuitry is connected to a first memory array of the first semiconductor structure. The second peripheral circuitry is connected to a second memory array of the second semiconductor structure.

Another aspect of the present disclosure features a method including: providing semiconductor structures. Each of the semiconductor structures includes a memory array and a first circuitry coupled to the memory array. The method also includes providing at least one control structure including second circuitries and stacking the semiconductor structures on the at least one control structure along a direction and connecting each of the second circuitries to a memory array of a respective semiconductor structure of the semiconductor structures.

In some implementations, stacking the semiconductor structures on the at least one control structure includes at least one of: stacking semiconductor structures on opposite sides of a control structure of the at least one control structure along the direction, or stacking semiconductor structures on a same side of a control structure of the at least one control structure along the direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices.

FIG. 2 illustrates a block diagram of an example memory device.

FIG. 3 illustrates a top view of an example of a memory bank array.

FIG. 4 illustrates a simplified cross-section view of an example semiconductor device.

FIG. 5A illustrates a cross-section view of an example semiconductor structure.

FIG. 5B illustrates a top view of an example embedded DRAM cell array.

FIG. 5C illustrates a cross-section view of a part of example embedded DRAM cells.

FIG. 6 illustrates a cross-section view of an example of a control structure.

FIG. 7A illustrates a simplified cross-section view of an example semiconductor device with direct bonding.

FIG. 7B illustrates a cross-section view of an example semiconductor device.

FIG. 7C illustrates a cross-section view of an example semiconductor device.

FIG. 8A illustrates a simplified cross-section view of an example semiconductor device.

FIG. 8B illustrates a cross-section view of an example semiconductor device with two semiconductor structures.

FIG. 8C illustrates a cross-section view of an example semiconductor device with three semiconductor structures.

FIG. 9 illustrates a simplified cross-section view of an example semiconductor device.

FIG. 10 is a flowchart chart of an example process for forming a semiconductor device.

It is to be understood that the various exemplary implementations shown in the figures are merely illustrative representations and are not necessarily drawn to scale.

### DETAILED DESCRIPTION

One crucial aspect of memory devices is their storage density, which refers to the amount of data that can be stored within a given physical area. Higher storage density is desirable because it allows for more information to be stored in a compact space. As technology advances, there is a constant push to increase storage density to meet the growing demands for data storage in various applications, such as consumer electronics, data centers, and mobile devices. A memory device can be consisted of memory arrays and control circuitry. Memory arrays are organized structures of memory cells where data is stored. Control circuitry is responsible for controlling the operations, e.g., reading and writing, of these memory arrays. The control circuitry can be positioned in the areas between adjacent memory arrays and/or around the periphery of the multiple memory arrays. Increasing memory storage density can be challenging due to physical limitations, electrical interference, manufacturing difficulties, etc.

This disclosure describes a semiconductor device and a method to form such semiconductor device. In some aspects, the semiconductor device includes semiconductor structures and at least one control structure. Each of the semiconductor structures includes a memory array and a first circuitry coupled to the memory array. The control structure includes second circuitries for the semiconductor structures. Each of the second circuitries is coupled to a memory array of a respective semiconductor structure of the semiconductor structures. The semiconductor structures and the at least one control structure are stacked together along a direction.

Implementations of the present disclosure can provide one or more of the following technical advantages and/or benefits. First, control circuitries for controlling memory cell arrays can be divided into two parts, first circuitries and second circuitries (also called peripheral circuitries). The first circuitries can be positioned in the areas between adjacent memory arrays and/or around the periphery of multiple memory arrays. The first circuitries can be manufactured together with memory arrays on two or more semiconductor structures, while the second circuitries can be manufactured separately on one or more control structures. Because second circuitries are removed from the areas between adjacent memory arrays and/or the areas around the periphery area of multiple memory arrays, the separation distance between neighboring memory arrays and/or their surrounding space is reduced. The reduced separation distance increases the memory cell capacity within a given lateral area. The two or more semiconductor structures and the one or more control structures can be subsequently bonded together vertically to electrically couple the memory arrays and the second circuitries. The first circuitries and the second circuitries can be configured to function together to manage and control the operations of memory arrays. This semiconductor device with integrated semiconductor structures and control structures can functionally perform the same memory array control task as a single semiconductor structure upon which the first circuitries and the second circuitries are formed with the memory arrays.

Second, semiconductor structures and control structures can be manufactured separately on separate semiconductor substrates such that a limitation (e.g., thermal budget) of fabricating one of them does not limit the processes of fabricating another. High thermal budgets are often required for advanced manufacturing techniques, such as annealing processes in memory technologies. Because of enhanced thermal budget management, the techniques implemented herein give better control over the manufacturing processes, leading to improved yield and reduced variability in the performance of semiconductor devices.

Third, in contrast to the semiconductor structures which include both memory arrays and first circuitries, the control structures can be configured to only include second circuitries without memory arrays, which may require less interconnection vias and/or conductive lines than the semiconductor structures. This enables larger pitches for via or interconnection contacts in the semiconductor structures, e.g., through-silicon-vias (TSV), through-silicon-contact (TSC), or other types of vias. This larger pitch contributes to a broader process window, which, in turn, simplifies the manufacturing process and reduces costs.

Fourth, a memory cell with buried word lines, e.g., buried DRAM or 6F2 DRAM cells, can be deployed with the techniques implemented herein. For buried DRAM cells, word lines, bit lines, and capacitors can be manufactured on one side of the semiconductor substrates. The first circuitries can be manufactured on the same side of the semiconductor substrate together with memory cell arrays. The advantage of burying the word lines in the substrate can include: reducing parasitic capacitance and improving the overall performance of the DRAM cell. Parasitic capacitance refers to unwanted capacitance that exists between conductive elements and can slow down the operation of the circuit. In addition, the channel length is increased in buried DRAM cells, allowing for better control of the flow of current between the source and drain terminals. The techniques enable the memory devices to achieve higher storage capacity and better device performance.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

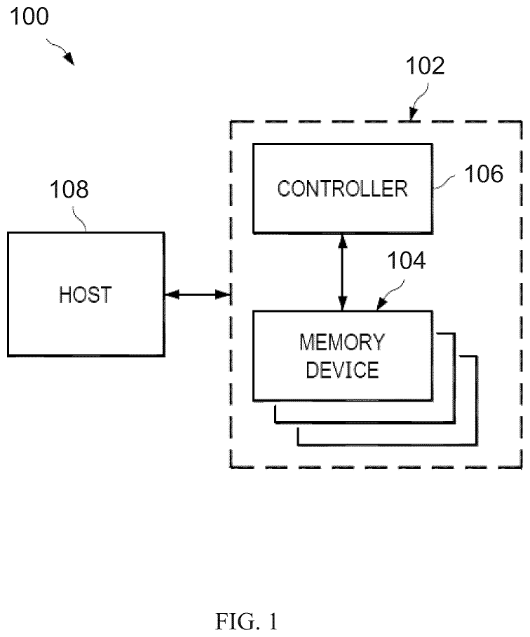

FIG. 1 illustrates an example of a block diagram of system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data to or from memory devices 104.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104.

Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

In some implementations, the memory system 102 does not include the memory controller 106, and the host 108 is coupled to the memory device 104 directly. The memory controller 106 may be located in the host 108. Alternatively, the host 108 may not include the memory controller 106 either but may be configured to perform functions similar to what the memory controller 106 does as described above.

Memory device 104 can be any memory device disclosed in the present disclosure.

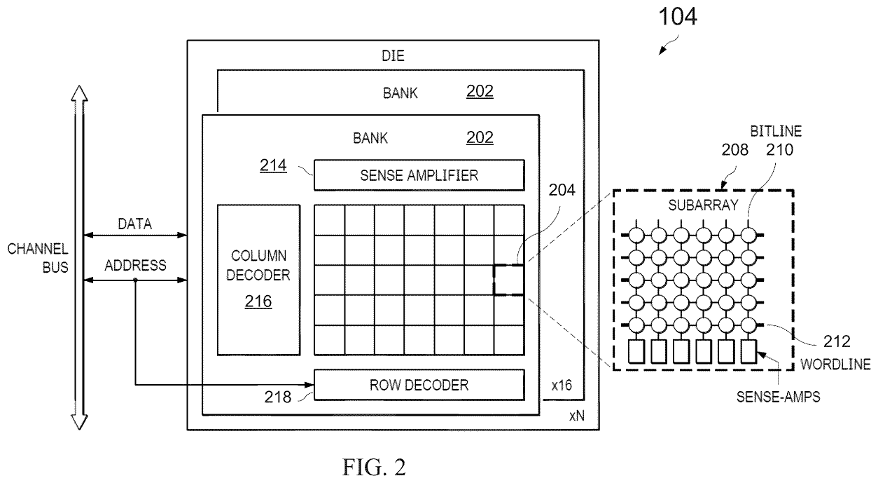

FIG. 2 illustrates a block diagram of an example memory device 104, according to some aspects of the present disclosure. The memory device 104 includes a set of memory banks 202. Each memory bank 202 includes a memory array 204 (also referred to as a memory cell array) having memory cells arranged in rows and columns. The memory array 204 may be divided into a number of memory sub-arrays 208 for efficient wiring and low power consumption. In some implementations, each or at least one of the memory cells includes a phase change memory (PCM) element. The PCM element may be programmed to either a set state or a reset state to store data as described above. Each memory cell is connected to a bit line 210 and a word line 212. Each memory bank 202 includes a data buffer/sense amplifier 214, a column decoder/bit line driver 216, and a row decoder/word line driver 218. In some examples, additional peripheral circuits or control circuitry not shown in FIG. 2 may be included as well.

Data buffer/sense amplifier 214 can be configured to read and program (write) data from and to memory cell array 204 according to control signals from a memory controller (e.g., the memory controller 106 of FIG. 1). In one example, data buffer/sense amplifier 214 may store one codeword of program data (write data) to be programmed into memory cell array 204. In another example, data buffer/sense amplifier 214 may perform program verify operations to ensure that the data has been properly programmed into select memory cells coupled to selected word lines 212. In yet another example, data buffer/sense amplifier 214 may also sense the low power signals from bit line 210 that represents a data bit stored in a memory cell and amplify the small voltage swing to recognizable logic levels in a read operation.

Column decoder/bit line driver 216 may be connected to the memory cell array 204 via bit lines and select/drive one or more bit lines to perform an operation on memory cell coupled to a selected bit line. Row decoder/word line driver 218 may be connected to the memory cell array 204 via word lines and select/drive one or more word lines to perform an operation on memory cell coupled to a selected word line. In some cases, when a particular row (word line) needs to be accessed for a read or write operation, the word line driver 218 can activate a word line by sending appropriate signals. Once the word line is activated, the memory cells connected to the word line become accessible for read or write operations. The specific operation performed on the memory cells can include reading the data stored in the cells or writing new data into them.

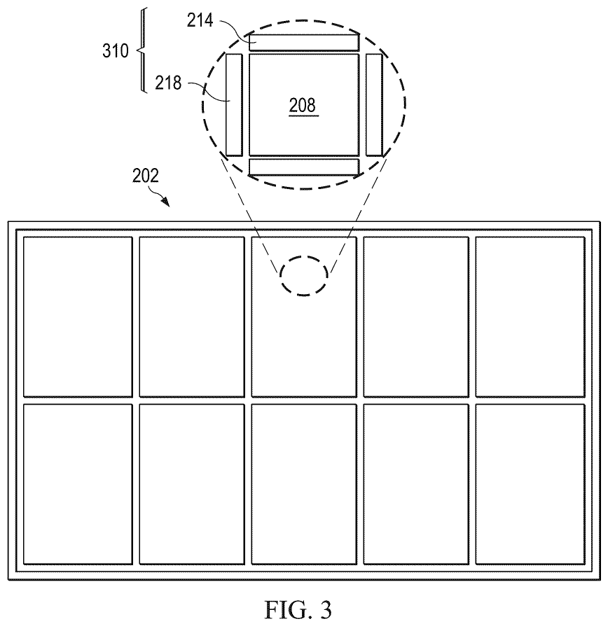

FIG. 3 illustrates a top view of an example of a memory bank array. As described above, each memory bank includes one or more memory subarray 208. The memory subarray 208 are arranged close to each other to achieve higher compacity. Control circuitries are used to control the operations of memory cells in the memory subarrays 208. In some implementations, the control circuitry includes, without limitation to, sense amplifiers 214, word line drivers 218, input-output (I/O) circuitry, address decoders, row and column address buffers, read/write control logic, row and column decoders, clock generation and control, Error Correction Code (ECC) logic, power management circuitry, any combination thereof, or any other suitable circuitry.

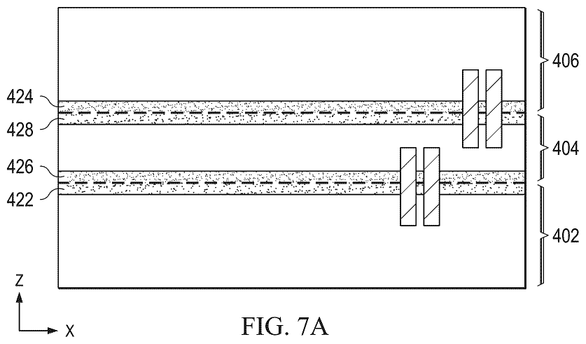

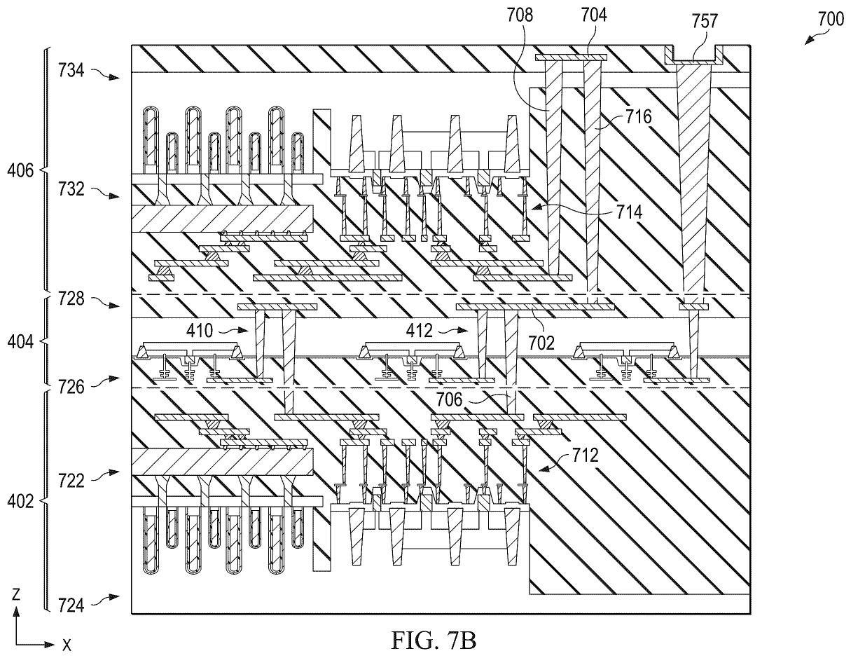

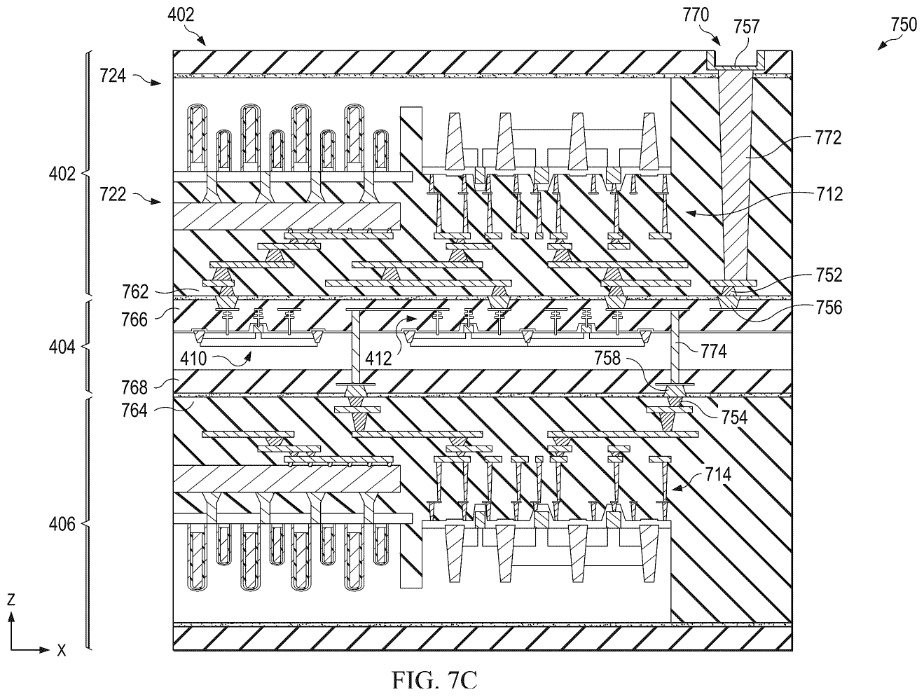

To achieve a higher memory cell capacity, the control circuitry can be divided into two or more parts, e.g., first circuitry and second circuitry. In some implementations, only the first circuitry is manufactured together with the memory subarrays 208, as illustrated in FIG. 3. The second circuitry is formed separately, e.g., on a separate substrate. The second circuitry is subsequently coupled with the first circuitry through bonding process, as described with further details in FIG. 7A. Multiple parts of the control circuitry function together to control and manage the operations of memory arrays. Second circuitries in this disclosure are also referred as peripheral circuitries.

In some implementations, as illustrated in FIG. 3, the first part of the control circuitry, e.g., first circuitry, can include sense amplifiers 214, which amplify the small signals read from memory cells to a level that can be reliably interpreted. Alternatively, or in addition, the first part of the control circuitry, e.g., first circuitry, includes word line drivers 218, which activate the appropriate word lines to enable the read or write operation on a specific memory cell. It understood that the first part of control circuitry can include, in addition, or alternatively, other suitable circuitries.

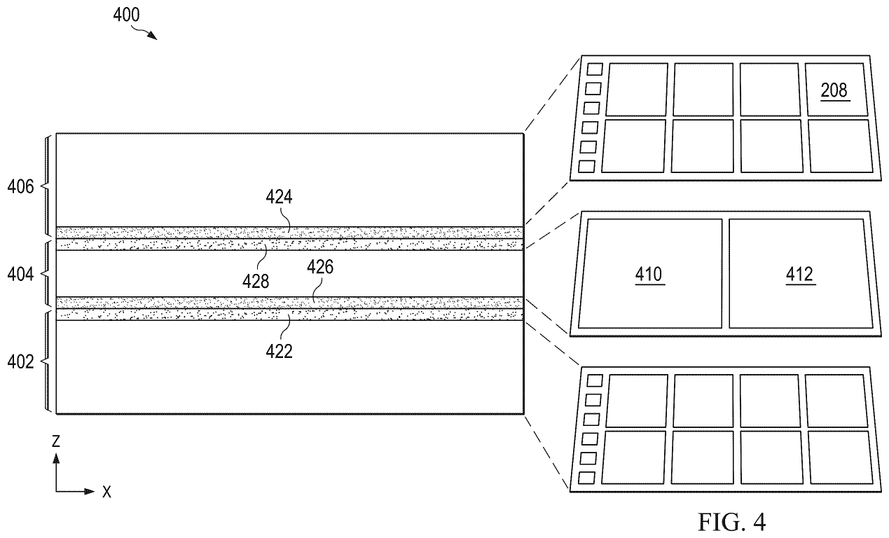

FIG. 4 illustrates a simplified cross-section view of an example of an integrated semiconductor device 400. The semiconductor device 400 includes a first semiconductor structure 402, a second semiconductor structure 406 and a control structure 404. Each semiconductor structure can include one or more memory arrays. As noted above, each of the control circuitries for the corresponding memory arrays can be divided into a first circuitry and a second circuitry. Second circuitries in this disclosure can be also referred as peripheral circuitries. Memory arrays and the first circuitries can be manufactured in semiconductor structures (402, 406), while the second circuitries or peripheral circuitries can be manufactured in the control structure 404. In some implementations, the first semiconductor structure 402 has an identical design layout as the second semiconductor structure 406. In some implementations, the semiconductor structures (402, 406) and the control structure 404 are manufactured separately on separate substrates such that a limitation (e.g., thermal budget) of fabricating one of them does not limit the processes of fabricating another. In some implementations, the semiconductor structures (402, 406) and the control structure 404 are fabricated in parallel on a same substrate through design of photolithography masks. In some implementations, the semiconductor structures (402, 406) and the control structure 404 are integrated by direct bonding or hybrid bonding, as described with further details in FIGS. 7A-7C.

In some implementations, the first circuitry includes one or more sense amplifiers 214. In some implementations, the first circuitry includes one or more word line drivers 218. In some implementations, the first circuitry includes both sense amplifiers 214 and word line drivers 218. In some implementations, the second circuitry or the peripheral circuitry includes input-output (I/O) circuitry configured to communicate with one or more external devices.

In some implementations, the control structure 404 includes two second circuitries, e.g., a first peripheral circuitry 410 and a second peripheral circuitry 412. As illustrated in FIG. 4, the first peripheral circuitry 410 and the second peripheral circuitry 412 are disposed laterally along X direction. The first peripheral circuitry 410 can be connected with the first circuitry and/or the memory array in the first semiconductor structure 402, while the second peripheral circuitry 412 can be connected with the first circuitry and/or the memory array in the second semiconductor structure 406. In some implementations, the first peripheral circuitry 410 and the second peripheral circuitry 412 are connected through interconnection conductive lines and vias/contacts on the control structure 404.

The semiconductor structures (402, 406) and the control structure 404 are integrated to establish a connection among the memory arrays, the first circuitries and the peripheral circuitries. The first peripheral circuitry 410, the second peripheral circuitry 412, the first circuitry in the first semiconductor structure 402, and the first circuitry in the second semiconductor structure 406 are configured to function together to manage and control the operations of memory arrays in the semiconductor structures (402, 406).

In some implementations, as illustrated in FIG. 4, the semiconductor structures (402, 406) are integrated on opposite side of the control structure 404. The first semiconductor structure 402 can include a memory array, a first circuitry and a first bonding layer 422. The first circuitry and the first bonding layer 422 are in a first side of the first semiconductor structure 402. The second semiconductor structure 406 includes a memory array, a first circuitry and a second bonding layer 424. The first circuitry of the second semiconductor structure 406 and the second bonding layer 424 are in a first side of the second semiconductor structure 406. The control structure 404 has a third bonding layer 426 and a fourth bonding layer 428 on the opposite sides. The first semiconductor structure 402 and the control structure 404 are integrated with the first bonding layer 422 being in contact with the third bonding layer 426. The second semiconductor structure 406 and the control structure 404 are integrated with the second bonding layer 424 being in contact with the fourth bonding layer 428. The first peripheral circuitry 410 is connected with the memory array of the first semiconductor structure 402. The second peripheral circuitry 412 is connected with the memory array of the second semiconductor structure 406. The memory array of the first semiconductor structure 402 can be also referred as the first memory array in this disclosure. The memory array of the second semiconductor structure 406 can be also referred as the second memory array in this disclosure.

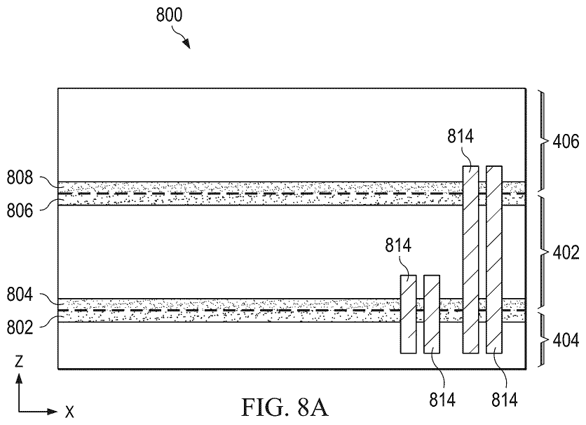

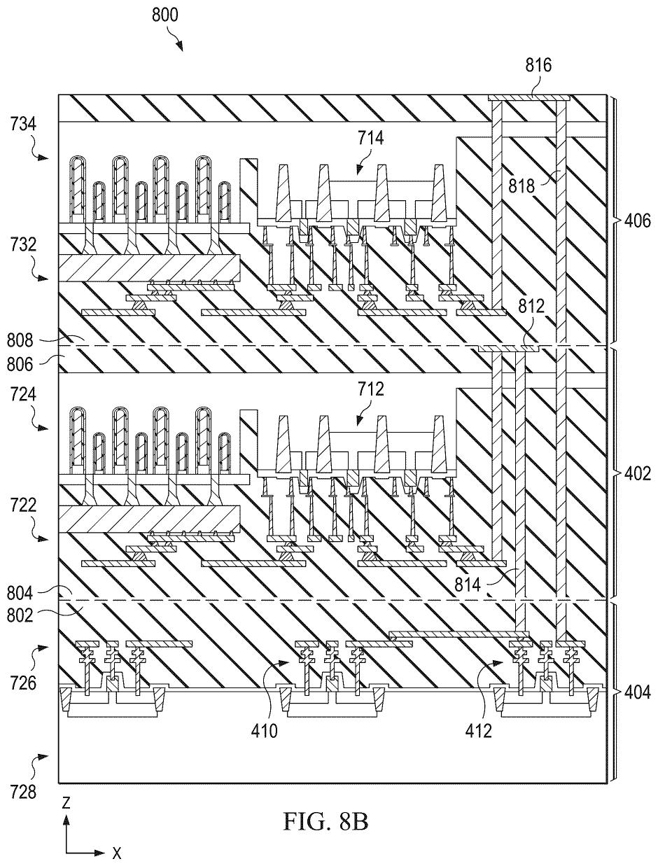

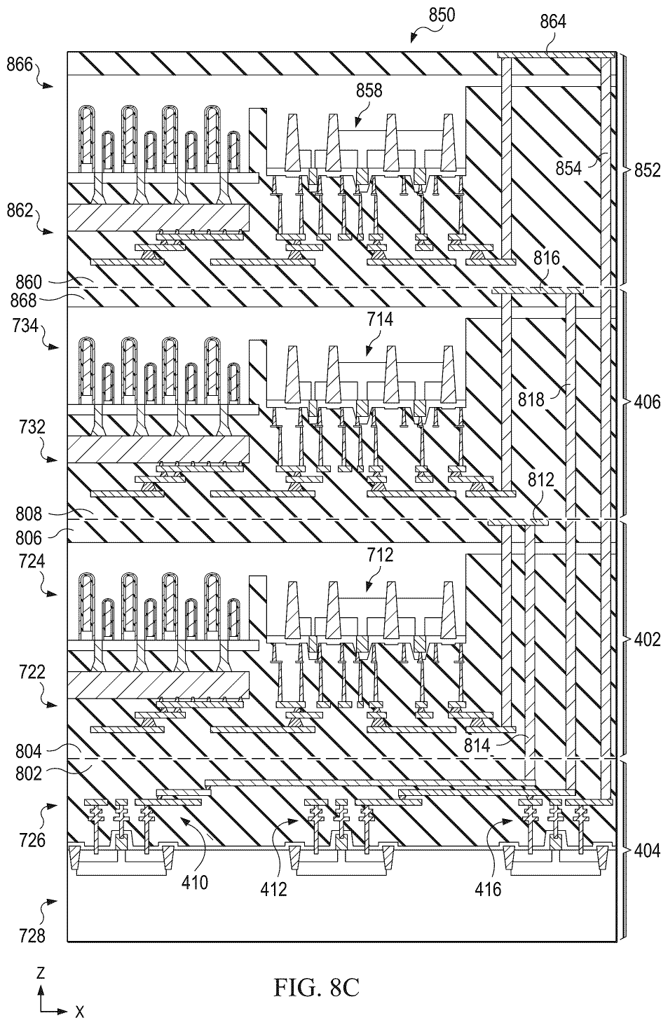

An interconnection conductive structure and conductive vias can be formed on the semiconductor device 400, as described with further details in FIGS. 7B-7C and 8B. The interconnection conductive structure can be used to establish the communication between the semiconductor structures (402, 406) and the control structure 404. In addition, the interconnection conductive structure can include a pad-out structure to connect with one or more external devices, e.g., a power source. In some implementations, the interconnection conductive structure is deployed with conductive contacts, as described below in FIG. 7C, at bonding interfaces to connect the first circuitries in the semiconductor structures (402, 406) and the second circuitries (also called the peripheral circuitries in this disclosure) in the control structure 404.

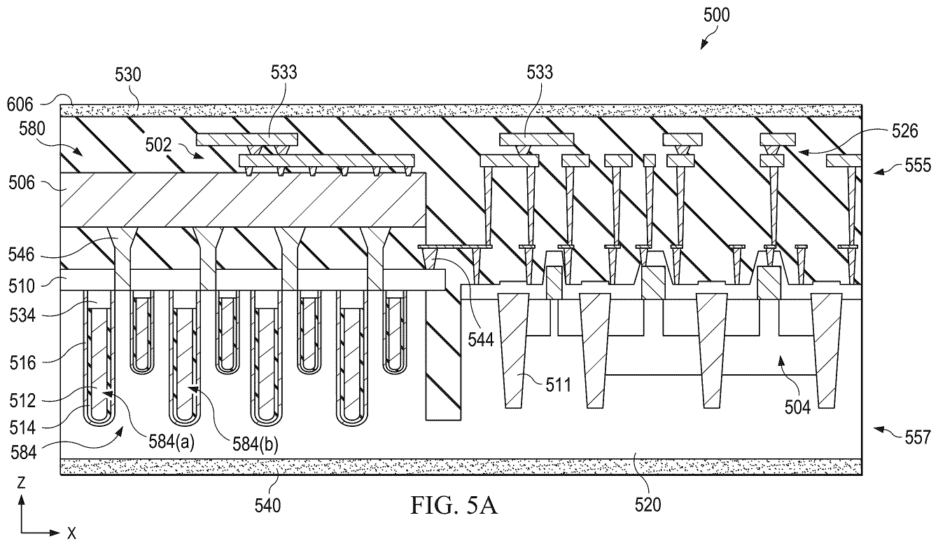

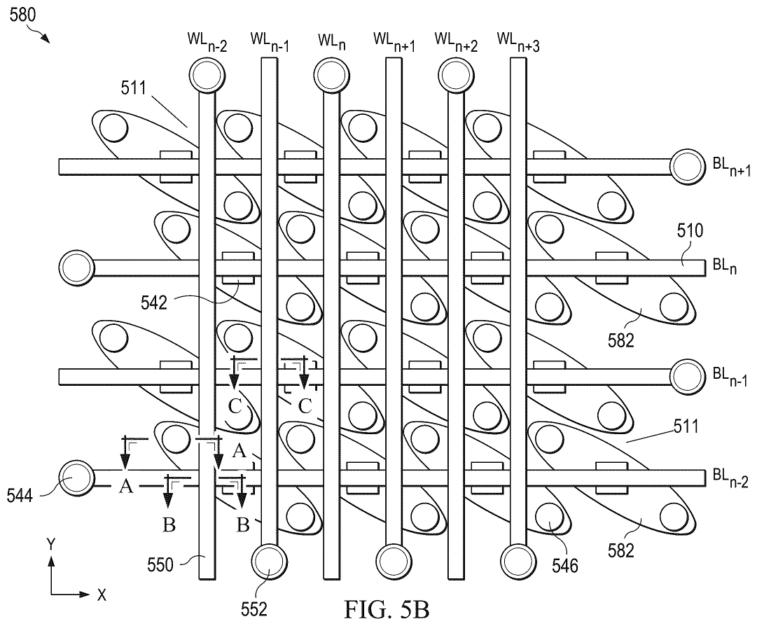

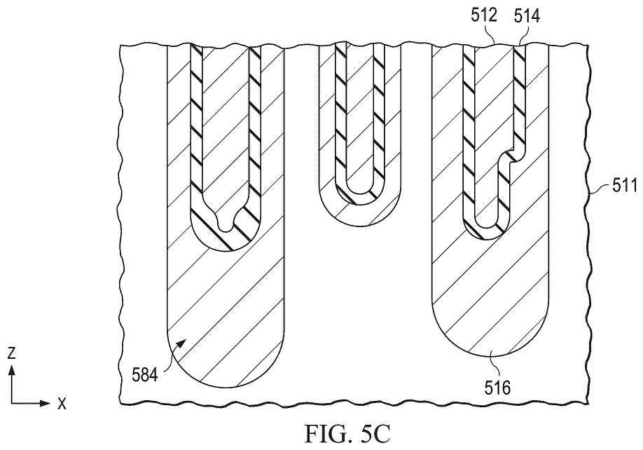

FIG. 5A illustrates a cross-section view of an example semiconductor structure 500. FIG. 5B illustrates a top view of an example of an embedded DRAM cell array. FIG. 5C illustrates a cross-section view of a part of example embedded DRAM cells. As used herein, whether one component (e.g., a layer or a device) is “on,” “above,” or “below” another component (e.g., a layer or a device) of a semiconductor structure is determined relative to the substrate of the semiconductor structure (e.g., substrate 520) in the z-direction (i.e., the vertical direction) when the substrate is positioned in the lowest plane of the semiconductor structure in the z-direction.

The semiconductor structure 500 can be implemented as the first semiconductor structure 402 and/or the second semiconductor structure 406 in FIG. 4. The semiconductor structure 500 can include a memory array 502 and a first circuitry 504. The memory array 502 can be one or more memory subarrays 208 in FIGS. 2-3. The first circuitry 504 can include sense amplifier 214 and/or word line driver 218 in FIGS. 2-3. The sense amplifier 214 is coupled to a corresponding bit line of memory arrays. The word line driver 218 is coupled to a corresponding word line of memory arrays. In some implementations, as illustrated in FIG. 5A, the memory array 502 and the first circuitry 504 are arranged laterally along X direction on a substrate 520.

In some implementations, the memory array 502 includes an embedded DRAM cell array. An embedded DRAM cell array 580 includes a plurality of cell pairs. Referring to FIG. 5B, each pair of cells are in an active area 582 in the substrate 520. In some implementations, the active area 582 of the substrate 520 is formed by implanting dopants into a semiconductor substrate. The dopants can be with N+ type dopants (e.g., Phosphorus (P) or Arsenic (As)) or P-type dopants (e.g., Boron (B) or Gallium (Ga)) at a desired doping level.

As illustrated in FIG. 5B, the active area 582 can have a longitude axis oriented at an angle relative to the X direction. Each longitude active area 582 can extend vertically along Z direction into the substrate 520 as illustrated in FIGS. 5A and 5C. FIG. 5C illustrates that each cell pair can be isolated from its neighboring cell pairs by shallow trench isolation (STI) 511 with one or more dielectric materials. The STI 511 can be formed on the silicon substrate 520 (not shown in FIG. 5C). FIG. 5A illustrates each cell pair can be isolated from each other by the silicon substrate 520, and the silicon substrate 520 can have different dopants or doping levels from the channels 516 or the active areas 582. In some implementations, each cell pair is isolated by LOCOS (localized oxidation of silicon) isolation or buried oxide (BOX) isolation.

Referring to FIG. 5B, each cell pair can include two cells which share a bit line contact 542 and thus connect to a same bit line 510. The bit line contact 542 is not shown in FIGS. 5A and 5C. Each cell includes a transistor 584 and a capacitor 506. The transistor 584 can include a drain terminal, a source terminal, and a gate. The capacitor 506 can be connected to a source terminal of the transistor 584 through the source contact 546 and used to store a charge. The charge represents a bit of information. The transistor 584 can be used as a switch for the capacitor 506. A source contact 546 connects the source terminal of the transistor 584 with a corresponding capacitor 506, as illustrated in FIG. 5A. The source contacts 546 for a cell pair can be distributed along the longitude axis of the active area 582, as illustrated in FIG. 5B. Although not shown in FIG. 5A, it is understood that each capacitor 506 is isolated from one another by dielectric materials. It is further understood that the capacitor 506 in FIG. 5A is for illustrative purposes only and doesn't accurately represent the true structures of capacitors. In some implementations, the source terminals or drain terminals of the transistors 584 are doped with N+ type dopants (e.g., Phosphorus (P) or Arsenic (As)) or P-type dopants (e.g., Boron (B) or Gallium (Ga)) at a desired doping level, or comprise Silicon Germanium (SiGe).

In some implementations, the gate 512 for a transistor 584 is surrounded by a U shape or a quasi-U shape gate dielectric layer 514, e.g., as illustrated in FIGS. 5A and 5C. Although FIG. 5C shows different shapes of gate dielectric layer 514 in adjacent memory cell pairs, it is understood that in a memory array 502 adjacent memory cell pairs can have same or similar shape of gate dielectric layer 514. The gate 512 can be part of a word line 550. The gate dielectric layer 514 can be surrounded by the channel materials (e.g., doped silicon). In other words, the gate 512, the gate dielectric layer 514, and the channels 516 can be arranged radially from the center toward the outer surface of each active area 582. Each active area 582 can be isolated from its neighboring active area by shallow trench isolation (STI) 511 with dielectric materials (as shown in FIG. 5C). In some implementations, the gate dielectric layer 514 of the transistor 584 includes a dielectric material, such as silicon oxide, silicon nitride, or high-k dielectrics including, but not limited to, Al2O3, HfO2, Ta2O5, ZrO2, TiO2, or any combination thereof. In some implementations, the gate 512 includes a conductive material including, but not limited to W, Co, Cu, Al, TiN, TaN, polysilicon, silicide, or any combination thereof.

A plurality of word lines 550 can be buried in the substrate 520 and extending through multiple active areas 582 along Y axis, e.g., as illustrated in FIG. 5B. In some implementations, a corresponding part of the word line 550 is utilized as a gate 512 for each transistor 584. The word line 550 controls the reading or writing operations of the memory cells. A plurality of bit lines 510 extends with an angle with respective to the word lines 550 and is disposed between the word lines 550 and the capacitors 506 along Z axis, e.g., as illustrated in FIG. 5A. In some implementations, the bit lines 510 are perpendicular to the word lines 550, e.g., as illustrated in FIG. 5B. In some implementations, the bit lines 510 are non-orthogonal to the word lines 550 (not shown). The advantages of burying the word lines in the substrate can include reducing parasitic capacitance and improving the overall performance of the DRAM cell. In addition, the channel length can be increased with buried word lines, allowing for better control of the flow of current between the source and drain terminals.

FIG. 5A illustrate relative positions of devices or structures in an example memory array 502 along Z direction. For example, the bit lines 510 are situated between the capacitors 506 and the transistors 584 along the Z direction. The gate 512, which is part of the word line 550, is embedded in the substrate 520. However, it is to be understood that that the devices or structures depicted in FIG. 5A can represent a composite view from multiple X-Z cross-sectional planes. Thus, FIG. 5A is for illustrative purpose only and does not depict a single cross-sectional view within an actual device. For example, the bit line 510 and the source contact 546 in FIG. 5A are in different X-Z cross-sectional planes. Referring to FIG. 5B, the bit line 510 can be in the cross-sectional plane B-B, while the source contact 546 can be in cross-sectional plane A-A. The bit line 510 and the source contact 546 are isolated by dielectric material along Y-direction, although such isolation is not shown in FIG. 5A. In another example, the transistor 584(a) and the transistor 584(b) in FIG. 5A can be in different X-Z cross-sectional planes. For example, as illustrated in FIG. 5B, the transistor 584(a) can be located in the cross-sectional plane B-B, while the transistor 584(b) can be located in cross-sectional plane C-C. Similar interpretations also apply to FIG. 5C. Individual transistor 584 in FIG. 5C can be in different X-Z cross-sectional planes.

Further, referring back to FIG. 5B, while the X-Y plane view shows intersecting bit lines 510 and word lines 550, an isolating material is situated between these two lines along the Z direction. As shown in FIG. 5A, the gate 512, which is part of the word line 550, is isolated from the bit line 510 by a dielectric material 534 along the Z direction.

Although not shown, it is understood that the memory array 502 can include any other types of memory cells, including without limitation to, NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others.

Each word line 550 can be connected to a word line pad 552 at one end, e.g., as illustrated in FIG. 5B. To realize a more compact configuration, the word line pads 552 can be arranged in opposite ends of adjacent word lines 550. For example, the word line contact for WLn-2 can be located on a positive end of the word line WLn-2 along a positive Y axis, while the word line pad 552 for WLn-1 can be located on a negative end of the word line along a negative Y axis. Likewise, the bit line pads 544 can also be arranged in opposite ends of adjacent bit lines 510 for a compact configuration.

As shown in FIG. 5A, the semiconductor structure 500 has a first side 555 and a second side 557. The first side 555 can be along the positive Z direction, e.g., the front side of the substrate 520. The second side 557 is opposite to the first side along the negative Z direction, e.g., the back side of the substrate 520. In some implementations, the bit lines 510 and the capacitors 506 can be arranged on one side of the word lines 550. In other words, the bit lines 510 are disposed between the word lines 550 and the capacitors 506 along Z direction. The word lines 550, bit lines 510 and the capacitors 506 can be formed consecutively on the first side 555 of the semiconductor structure 500. This configuration cases the process complexity to manufacture control circuitries, e.g., first circuitry 504, which are configured to connect with the bit lines 510 and/or word lines 550 on the first side 555 of the semiconductor structure 500.

In some implementations, the bit lines 510, the word lines 550, the bit line pads 544, or the word line pads 552 are made of a conductive material including, but not limited to W, Co, Cu, Al, TiN, TaN, doped polysilicon, or any combination thereof. In some implementations, the bit lines 510, the word lines 550, the bit line pads 544, or the word line pads 552 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

The first circuitry 504 can include a first part of a peripheral circuitry configured to manage and control some operations of memory cells. As noted above, in some implementations, the first circuitry 504 includes a sense amplifier 214 and/or a word line driver 218. The sense amplifier 214 can be connected to a bit line 510 through bit line pad 544, which is configured to amplify and detect the small voltage difference that represents the stored data in a memory cell. The word line driver 218 can be connected a word line 550, which is configured to activate and control the word lines 550 in a memory array during read and/or write operations. In some implementations, the first circuitry 504 is connected to the memory array 502 through metal routings, e.g., metal lines 533.

The first circuitry 504 can be a CMOS (Complementary Metal-Oxide-Semiconductor) circuitry, which can be built by transistors, capacitors, resistors, diodes, bipolar junctions, inductors, varactors, or a combination thereof. The transistors can include NMOS transistors, PMOS transistors, and/or bipolar junctions. An NMOS transistor can include an n-type semiconductor (source and drain) and a P-type substrate. A PMOS transistor can have a P-type semiconductor with an n-type substrate. Bipolar junctions can include NPN and PNP transistors. In an NPN transistor, a thin layer of P-type semiconductor is sandwiched between two layers of N-type semiconductor. In a PNP transistor, a thin layer of N-type semiconductor is sandwiched between two layers of P-type semiconductor. The combination of these transistors allows for complementary logic, where one is ON while the other is OFF. Transistors can be isolated by trenches. Trench isolations (e.g., shallow trench isolations (STIs) 511) and doped regions (e.g., wells, sources, and drains of transistors) can be formed on or in the substrate as well. The combination of these components allows for the creation of complex digital and analog circuits for memory array control.

In some implementations, the semiconductor structure 500 further includes an interconnect layer 526 above the first circuitry 504 to transfer electrical signals to and from the first circuitry 504. The interconnect layer 526 can include a plurality of interconnects (also referred to herein as “contacts”), including lateral interconnect lines, e.g., metal lines, and VIA contacts. The interconnect layer 526 can further include one or more interlay dielectric (ILD) layers in which the interconnect lines and via contacts can form. That is, the interconnect layer 526 can include interconnect lines and via contacts in multiple ILD layers. In some implementations, transistors in the first circuitry 504 are coupled to one another through the interconnects in the interconnect layer 526. The interconnects in interconnect layer 526 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 5A, the semiconductor structure 500 has a front side, e.g., the first side 555, and a back side, e.g., the second side 557. The semiconductor structure 500 can include a first bonding layer 530 at the first side 555 of the semiconductor structure 500 and above the interconnect layer 526. The first bonding layer 530 can be the first bonding layer 422 or the second bonding layer 424 in FIG. 4. In some implementations, the semiconductor structure 500 can include a second bonding layer 540 at the second side 557 of the semiconductor structure 500. The second bonding layer 540 can be the first bonding layer 422 or the second bonding layer 424 in FIG. 4.

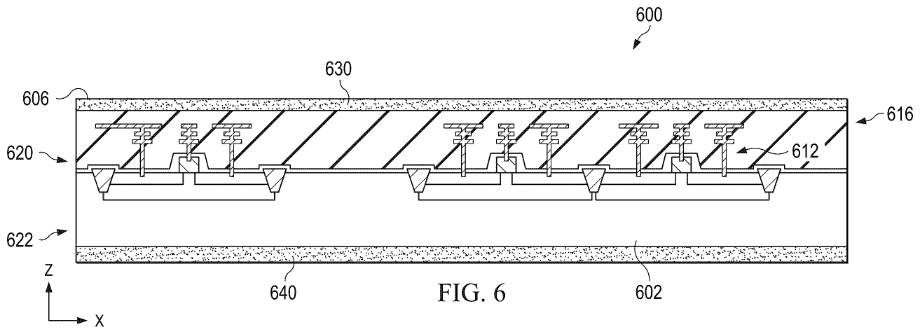

In some implementations, as described below in FIG. 7C, the bonding layers 530, 540 include a plurality of bonding contacts and dielectrics electrically isolating the bonding contacts. The bonding contacts can include conductive materials, such as Cu. The remaining area of the bonding layer 530 can be formed with a dielectric material, such as silicon oxide. The bonding contacts and surrounding dielectric material in the bonding layer 530 can be used for hybrid bonding. Similarly, as described below in FIG. 6, the control structure 404 can also include a bonding layer and/or bonding contacts at the bonding interface. In some implementations, the bonding layers are not separate layers deposited onto the semiconductor structures. The bonding layers can refer to the bonding interface with diffused atoms between two or more semiconductor structures and/or control structures. In some implementations, the bonding layers can be separate layers formed on the semiconductor structures or control structures for gluing or adhesive purposes.

In some implementations, the memory array 502 and the first circuitry 504 are formed by a plurality of processes including, but not limited to, photolithography, dry/wet etch, thin film deposition, thermal growth, implantation, chemical mechanical polishing (CMP), and any other suitable processes. Dielectric material can be deposited using one or more thin film deposition processes, including, but not limited to, chemical vapor deposition (CVD), physical vapor deposition (PVD), atomic layer deposition (ALD), sputtering, or any combination thereof. Conductive material can be can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. The etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 6 illustrates a cross-section view of an example of a control structure 600. The control structure 600 can be the control structure 404 in FIG. 4. The control structure 600 can include a substrate 602, which can include silicon (e.g., single crystalline silicon, c-Si), SiGe, GaAs, Ge, SOI, or any other suitable materials. The control structure 600 includes one or more second circuitry 612, e.g., the second part of the control circuitries, on the substrate 602. In some implementations, the one or more second circuitry 612 is identical to one another. In some implementations, the second circuitry 612 is the first peripheral circuitry 410 or the second peripheral circuitry 412 in FIG. 4. The second circuitry 612 can also be the combination of the first peripheral circuitry 410 and the second peripheral circuitry 412 in FIG. 4.

In some implementations, the second circuitry 612 includes input-output (I/O) circuitry configured to communicate with one or more external devices. In some implementations, the second circuitry 612 includes address decoders, row and column address buffers, read/write control logic, row and column decoders, clock generation and control, Error Correction Code (ECC) logic, power management circuitry, any combination thereof, or any other suitable circuitry. The second circuitry 612 is configured to function together with the first circuitry 504 for each semiconductor structure 500 to control and manage the operations of memory arrays 502.

In some implementations, the second circuitry 612 include a plurality of transistors (e.g., planar transistors and/or 3D transistors). Trench isolations (e.g., shallow trench isolations (STIs)) and doped regions (e.g., wells, sources, and drains of transistors) can be formed on or in the substrate 602 as well. In some examples, the second circuitry 612 are formed using complementary metal-oxide-semiconductor (CMOS) technology, and the control structure 600 can be also formed on a semiconductor die that can be referred to as a control die or a CMOS die.

In some implementations, the control structure 600 further includes an interconnect layer 616 above the second circuitry 612 to transfer electrical signals to and from the second circuitry 612. The interconnect layer 616 can include a plurality of interconnects (also referred to herein as “contacts”), including lateral interconnect lines and VIA contacts. The interconnect layer 616 can further include one or more interlay dielectric (ILD) layers in which the interconnect lines and via contacts can form. That is, the interconnect layer 616 can include interconnect lines and via contacts in multiple ILD layers. In some implementations, the second circuitry 612 are coupled to one another through the interconnects in the interconnect layer 616. The interconnects in interconnect layer 616 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 6, the control structure 600 has a front side 620 and a back side 622, and the control structure 600 can include a third bonding layer 630 above the interconnect layer 616 and the second circuitry 612. In some implementations, the control structure 600 can further include a fourth bonding layer 640 at the back side 622 of the substrate 602. The bonding layers 630, 640 can be implemented as the third bonding layer 426 and/or the fourth bonding layer 428 as illustrated in FIG. 4.

In some implementations, the bonding layers (630, 640) can include a plurality of bonding contacts, as described below in FIG. 7C and a dielectric material electrically isolating the bonding contacts. The bonding contacts can include a conductive material, such as Cu. The remaining area of the bonding layers can be formed with a dielectric material, such as silicon oxide. The bonding contacts and the surrounding dielectric material in the bonding layer can be used for hybrid bonding. The bonding contacts can be in contact with the bonding contacts of the semiconductor structure at the bonding interfaces, as described below in FIG. 7C.

FIG. 7A illustrates a simplified cross-section view of an example semiconductor device with direct bonding. As described above in FIG. 4, the semiconductor structures (402, 406) can be integrated on opposite side of the control structure 404. The first semiconductor structure 402 can include a first circuitry and a first bonding layer 422. The first circuitry and the first bonding layer 422 are in a first side of the first semiconductor structure 402. The second semiconductor structure 406 comprises a first circuitry and a second bonding layer 424. The first circuitry of the second semiconductor structure 406 and the second bonding layer 424 are in a first side of the second semiconductor structure 406. The control structure 404 has a third bonding layer 426 and a fourth bonding layer 428 on the opposite sides. The first semiconductor structure 402 and the control structure 404 can be integrated with the first bonding layer 422 being in contact with the third bonding layer 426. The second semiconductor structure 406 and the control structure 404 can be integrated with the second bonding layer 424 being in contact with the fourth bonding layer 428. The control structure 404 can include a first peripheral circuitry 410 and a second peripheral circuitry 412 in the first side of the control structure 404. The first peripheral circuitry 410 can be connected with the memory array in the first semiconductor structure 402. The second peripheral circuitry 412 can be connected with the memory array in the second semiconductor structure 406.

In some implementations, the semiconductor structures (402, 406) are integrated on opposite side of the control structure 404 through direct bonding. In some implementations, the direct bonding involves oxide bonding. The surfaces of the two semiconductor substrates are prepared by cleaning the surfaces thoroughly to remove any contaminants and oxides. An oxide layer is grown or deposited on the surfaces of the first side of the two semiconductor substrates. The oxide layer can include silicon dioxide (SiO2). The two semiconductor structures can be then aligned to have a proper match. The integrated semiconductor structures can be subjected to high-temperature annealing. During annealing, the oxide layer becomes porous, and atoms at the interface diffuse and rearrange, forming strong covalent bonds between the substrates. After annealing, the bonded substrates are gradually cooled down. This allows the formation of strong bonds between the semiconductor materials.

In some implementations, the direct bonding involves molecular or atomic bonding. The surfaces of the two semiconductor substrates can be prepared by cleaning the surfaces thoroughly to remove any contaminants and oxides. The two semiconductor structures can be then aligned to have a proper match. The aligned semiconductor structures can be brought into a close contact. The van der Waals forces and other attractive forces between the atoms on the surfaces can help to hold the semiconductor structures together. The bonded semiconductor structures are subjected to high-temperature annealing. This heat treatment is typically done in a vacuum or controlled atmosphere to facilitate the migration of atoms at the interface and promote the formation of covalent bonds. After annealing, the bonded substrates are gradually cooled down. This allows the formation of strong bonds between the semiconductor materials.

In some implementations, the semiconductor structures (402, 406) are integrated on opposite side of the control structure 404 through hybrid bonding. Conductive contacts, as described below in FIG. 7C, can be formed at bonding interfaces to connect the array circuitries in the semiconductor structures (402, 406) and the control circuitries in the control structure 404.

In some implementations, the control structure 404 is thinned at one side or both sides before bonding with the first semiconductor structure 402 and/or the second semiconductor structure 406. The thinning of the control structure 404 can include mechanical thinning (e.g., grinding, polishing, and/or chemical mechanical polishing (CMP)), chemical thinning (e.g., wet etching, dry etching), laser thinning, acoustic thinning, or any combination thereof.

In some implementations, an interconnection conductive structure and conductive vias are formed on the semiconductor device, as described with further details in FIGS. 7B-7C. The interconnection conductive structure can be used to establish the communication between the semiconductor structures (402, 406) and the control structure 404. In addition, interconnection conductive structure can include a pad-out structure to connect with one or more external devices, e.g., a power source.

FIG. 7B illustrates a cross-section view of an example semiconductor device 700. The semiconductor device 700 includes a first semiconductor structure 402, a second semiconductor structure 406 and a control structure 404. The control structure 404 is integrated together with the first semiconductor structure 402 and the second semiconductor structure 406, resembling the configuration as shown in FIG. 7A. In some implementations, the integration is conducted through a direct bonding technique.

In some implementations, the first semiconductor structure 402 includes a first circuitry 712. The first circuitry 712 and the first bonding layer 422 (e.g., as illustrated in FIG. 7A) are in a first side 722 of the first semiconductor structure 402. The second semiconductor structure 406 includes a first circuitry 714. The first circuitry 714 and the second bonding layer 424 (e.g., as illustrated in FIG. 7A) are in a first side 732 of the second semiconductor structure 406. The control structure 404 includes a first peripheral circuitry 410 and a second peripheral circuitry 412 in the first side 726 of the control structure 404. In some implementations, the first peripheral circuitry 410 is connected with the memory array in the first semiconductor structure 402. The second peripheral circuitry 412 is connected with the memory array in the second semiconductor structure 406. In some implementations, the first peripheral circuitry 410 is connected with the first circuitry 712 of the first semiconductor structure 402. The second peripheral circuitry 412 is connected with the first circuitry 714 the second semiconductor structure 406.

In some implementations, a first conductive interconnection structure 702 is formed on a second side 728 of the control structure 404. The first peripheral circuitry 410 and the second peripheral circuitry 412 are respectively connected to the first conductive interconnection structure 702. A second conductive interconnection structure 704 is formed on a second side 734 of the second semiconductor structure 406 that is opposite to the first side 732 of the second semiconductor structure 406 along the Z direction. The first circuitry 712 of the first semiconductor structure 402 is connected to the first peripheral circuitry 410 at least by a first conductive structure 706. The first conductive structure 706 is configured to couple the first circuitry 712 of the first semiconductor structure 402 with the first conductive interconnection structure 702. The first conductive structure 706 can extend through the first bonding layer 422 (referring to FIG. 7A), the third bonding layer 426 (referring to FIG. 7A), and the control structure 404 along the Z direction.

In some implementations, the first circuitry 714 of the second semiconductor structure 406 is connected to the second peripheral circuitry 412 at least by a second conductive structure 708 and a third conductive structure 716. The second conductive structure 708 is coupled between the first circuitry 714 and the second conductive interconnection structure 704. The third conductive structure 716 is coupled between the second conductive interconnection structure 704 and the first conductive interconnection structure 702. The second conductive structure 708 extends at least partially through the second semiconductor structure 406 along the Z direction. The third conductive structure 716 extends through the second semiconductor structure 406, the second bonding layer 424 (e.g., as illustrated in FIG. 7A), and the fourth bonding layer 428 (e.g., as illustrated in FIG. 7A) along the Z direction.

The conductive interconnection structures (702, 704) and the conductive structures (706, 708, 716) can work together to connect (i) the first peripheral circuitry 410 and the first circuitry 712 of the first semiconductor structure 402, and (ii) the second peripheral circuitry 412 and the first circuitry 714 of the second semiconductor structure 406. In some implementations, the first circuitry 712 of the first semiconductor structure 402 and the first circuitry 714 of the second semiconductor structure 406 are connected. All three structures (402, 404 and 406) function together to manage and control memory arrays.

In some implementations, the conductive interconnection structures (702, 704) include a plurality of interconnects (also referred to herein as “contacts”), including lateral interconnect lines and VIA contacts. The conductive interconnection structures (702, 704) can further include one or more interlay dielectric (ILD) layers in which the interconnect lines and via contacts can form. That is, the conductive interconnection structures (702, 704) can include interconnect lines and via contacts in multiple ILD layers. In some implementations, the conductive interconnection structures (702, 704) further include a power source structure 757 as illustrated in FIG. 7B to power the semiconductor device 700. The power structure 757 can also include a plurality of interconnects and VIA contacts. In some implementations, the conductive structures (706, 708, 716) are through-silicon-vias (TSV) or through-silicon-contact (TSC).

The interconnects in conductive interconnection structures (702, 704) and conductive structures (706, 708, 716) can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. The conductive interconnection structures (702, 704) and conductive structures (706, 708, 716) can be formed by a plurality of processes including, but not limited to, photolithography, dry/wet etch, thin film deposition, thermal growth, implantation, chemical mechanical polishing (CMP), and any other suitable processes. The dielectric structure, e.g., ILD layers, can be deposited using one or more thin film deposition processes, including, but not limited to, chemical vapor deposition (CVD), physical vapor deposition (PVD), atomic layer deposition (ALD), sputtering, or any combination thereof. The conductive interconnection structures (702, 704) and conductive structures (706, 708, 716) can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 7C illustrates a cross-section view of an example semiconductor device 750. The semiconductor device 750 includes a first semiconductor structure 402, a second semiconductor structure 406 and a control structure 404. The control structure 404 is integrated together with the first semiconductor structure 402 and the second semiconductor structure 406.

In some implementations, the integration is conducted through a hybrid bonding. A hybrid bonding can include a combination of metal-to-metal bonding and a direct bonding. For example, as illustrated in FIG. 7C, the first bonding layer 422 (e.g., as illustrated in FIG. 7A) of the first semiconductor structure 402 includes one or more first conductive contacts 752 isolated by a first dielectric material 762. The second bonding layer 424 (e.g., as illustrated in FIG. 7A) of the second semiconductor structure 406 includes one or more second conductive contacts 754 isolated by a second dielectric material 764. The third bonding layer 426 (e.g., as illustrated in FIG. 7A) of the control structure 404 includes one or more third conductive contacts 756 isolated by a third dielectric material 766. The fourth bonding layer 428 (e.g., as illustrated in FIG. 7A) of the control structure 404 includes one or more fourth conductive contacts 758 isolated by a fourth dielectric material 768. At least one of the first conductive contacts 752 is in contact with a corresponding one of the third conductive contacts 756. At least one of the second conductive contacts 754 is in contact with a corresponding one of the one or more fourth conductive contacts 758.

In some implementations, as illustrated in FIG. 7C, a conductive interconnection structure 770 is formed on a second side 724 of the first semiconductor structure 402. The second side 724 is opposite to the first side 722 of the first semiconductor structure 402 along the Z direction. The first peripheral circuitry 410 is connected to the conductive interconnection structure 770 by a first conductive structure 772 extending in the first semiconductor structure 402 along the Z direction. The first conductive structure 772 is coupled to at least one first conductive contact 752 and the corresponding third conductive contact 756.

In some implementations, the first circuitry 712 of the first semiconductor structure 402 is connected to the first peripheral circuitry 410 at least by one or more first conductive contacts 752 and the corresponding third conductive contacts 756. As illustrated in FIG. 7C, the first circuitry 714 of the second semiconductor structure 406 is connected to the second peripheral circuitry 412 by at least one of the second conductive contacts 754, the corresponding fourth conductive contacts 758 and a second conductive structure 774. The second conductive structure 774 at least partially extends through the control structure 404.

In some implementations, the first conductive structure 772 and/or the second conductive structure 774 are through-silicon-vias (TSV) or through-silicon-contact (TSC). Although not shown, the conductive interconnection structure 770 can include a plurality of interconnects (also referred to herein as “contacts”), including lateral interconnect lines, e.g., metal lines, and VIA contacts. The conductive interconnection structure 770 can further include one or more interlay dielectric (ILD) layers in which the interconnect lines and via contacts can form. That is, the conductive interconnection structure can include interconnect lines and via contacts in multiple ILD layers. In some implementations, the conductive interconnection structure 770 further includes a power source structure 757 as illustrated in FIG. 7C, which connects to an external power source to power the semiconductor device 750. The power structure 757 can also include a plurality of interconnects and VIA contacts.

The interconnects in conductive interconnection structure 770, the conductive structures (772, 774), and/or conduct contacts (752,754,756,758) can include conductive materials including, but not limited to, W, Co, Cu, Al, doped silicon, silicides, or any combination thereof. The ILD layers and/or the dielectric materials (762,764,766,768) can be formed with dielectric materials including, but not limited to, silicon oxide, silicon nitride, silicon oxynitride, low-k dielectrics, or any combination thereof. The conductive interconnection structure 770, the conductive structures (772, 774), and/or conduct contacts (752,754,756,758) can be formed by a plurality of processes including, but not limited to, photolithography, dry/wet etch, thin film deposition, thermal growth, implantation, chemical mechanical polishing (CMP), and any other suitable processes. Dielectric materials can be deposited using one or more thin film deposition processes, including, but not limited to, chemical vapor deposition (CVD), physical vapor deposition (PVD), atomic layer deposition (ALD), sputtering, or any combination thereof. Conductive materials can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 8A illustrates a simplified cross-section view of an example semiconductor device. As shown, the first semiconductor structure 402 and the second semiconductor structure 406 are integrated on a same side of the control structure 404. The control structure 404 can have a first bonding layer 802. The first semiconductor structure 402 can have a second bonding layer 804 in a first side of the first semiconductor structure 402. The first semiconductor structure 402 can further include a third bonding layer 806 in a second side of the first semiconductor structure 404 that is opposite to the first side of the first semiconductor structure along the Z direction. The second semiconductor structure 406 includes a fourth bonding layer 808. The first semiconductor structure 402 is stacked on the first control structure 404 with the first bonding layer 802 being in contact with the second bonding layer 804. The second semiconductor structure 406 is stacked on the first semiconductor structure 402 with the fourth bonding layer 808 being in contact with the third bonding layer 806.

In some implementations, the semiconductor structures (402, 406) and the control structure 404 are integrated through direct bonding or the hybrid bonding. The direct bonding and hybrid bonding techniques can be the same as or similar to the techniques described in FIGS. 7A and 7C.

In some implementations, an interconnection conductive structure and conductive structures 814 are formed on the semiconductor device, as described with further details in FIG. 8B. The interconnection conductive structure can be used to establish the communication between the semiconductor structures (402, 406) and the control structure 404. In addition, interconnection conductive structure can include a pad-out structure to connect with external devices, e.g., power source.

FIG. 8B illustrates a cross-section view of an example semiconductor device 800. The semiconductor device 800 includes a first semiconductor structure 402, a second semiconductor structure 406 and a control structure 404. The first semiconductor structure 402 and the second semiconductor structure 406 are integrated on the same side of the first control structure 404.

In some implementations, the first semiconductor structure 402 has a first circuitry 712. The first circuitry 712 of the first semiconductor structure 402 and the second bonding layer 804 are in the first side 722 of the first semiconductor structure 402. The second semiconductor structure 406 has a first circuitry 714. The first circuitry 714 of the second semiconductor structure 406 and the fourth bonding layer 808 are in a first side 732 of the second semiconductor structure 406. The first control structure 404 includes a first peripheral circuitry 410 and a second peripheral circuitry 412 in the first side 726 of the first control structure 404. The first peripheral circuitry 410 is connected to a first memory array of the first semiconductor structure 402. The second peripheral circuitry 412 is connected to a second memory array of the second semiconductor structure 406.

In some implementations, a first conductive interconnection structure 812 is formed on the second side 724 of the first semiconductor structure 402. The first conductive interconnection structure 812 is connected to the first circuitry 712 of the first semiconductor structure 402. The first circuitry 712 of the first semiconductor structure 402 is connected to the first peripheral circuitry 410 at least by a first conductive structure 814 coupled between the first conductive interconnection structure 812 and the first peripheral circuitry 410.

In some implementations, the first conductive structure 814 extends at least partially through the first semiconductor structure 402 along the Z direction. In some implementations, the first bonding layer 802 and the second bonding layer 804 are direct bonding, as illustrated in FIG. 8B. The first conductive structure 814 extends through the first semiconductor structure 402, the first bonding layer 802, and the second bonding layer 804. In some implementations, the first bonding layer 802 and the second bonding layer 804 are bonded together by hybrid bonding, e.g., as illustrated in FIG. 7C. The first conductive structure 814 can extend through part of the first semiconductor structure 402 to a bonding contact, e.g., first conductive contact 752, of the first bonding layer 802.

In some implementations, a second conductive interconnection structure 816 is formed on a second side 734 of the second semiconductor structure 406 that is opposite to the first side 732 of the second semiconductor structure 406 along the Z direction. The second conductive interconnection structure 816 is connected to the first circuitry 714 of the second semiconductor structure 406. The first circuitry 714 of the second semiconductor structure 406 is connected to the second peripheral circuitry 412 at least by a second conductive structure 818 coupled between the second conductive interconnection structure 816 and the second peripheral circuitry 412.

In some implementations, the second conductive structure 818 extends through at least partially through the second semiconductor structure 406 and at least partially through the first semiconductor structure 402 along the Z direction. In some implementations, the first semiconductor structure 402, the second semiconductor structure 406, and the first control structure 404 are bonded through direct bonding, as illustrated in FIG. 8B. The second conductive structure 818 extends all the way from the second side 734 of the second semiconductor structure 406 to the first side 726 of the first control structure 404. In other words, the second conductive structure 818 extends through the first semiconductor structure 402, the second semiconductor structure 406, the first bonding layer 802, the second bonding layer 804, the third bonding layer 806, and the fourth bonding layer 808. In some implementations, the first semiconductor structure 402, the second semiconductor structure 406, and the first control structure 404 are bonded through hybrid bonding, as illustrated in FIG. 7C. The second conductive structure 818 can include multiple conductive substructures. One conductive substructure extends through part of the second semiconductor structure 406. Another conductive substructure extends through part of the first semiconductor structure 404. Different conductive substructures are connected through bonding contacts of corresponding bonding layers. This configuration mitigates processing issues associated with deep conductive structures, e.g., increased fabrication complexity, poor thermal budgets, and/or high mechanical stress. In some implementations, both direct bonding and hybrid bonding are deployed. The second conductive structure 818 extends through one of the semiconductor structures and the corresponding bonding layers, but partially through the other semiconductor structure.

In some implementations, the conductive structures (814, 818) are through-silicon-vias (TSV) or through-silicon-contact (TSC). The conductive interconnection structures (812, 816) and the conductive structures (814, 818) can work together to connect (i) the first peripheral circuitry 410 and the first circuitry 712 of the first semiconductor structure 402, and (ii) the second peripheral circuitry 412 and the first circuitry 714 of the second semiconductor structure 406. In some implementations, the first circuitry 712 of the first semiconductor structure 402 and the first circuitry 714 of the second semiconductor structure 406 are connected. All three structures (402, 404 and 406) function together to manage and control memory arrays.

In some implementations, the conductive interconnection structures (812, 816) include a plurality of interconnects (also referred to herein as “contacts”), including lateral interconnect lines and VIA contacts. The conductive interconnection structures (812, 816) can further include one or more interlay dielectric (ILD) layers in which the interconnect lines and via contacts can form. That is, the conductive interconnection structures (812, 816) can include interconnect lines and via contacts in multiple ILD layers. In some implementations, the conductive interconnection structures (812, 816) further include a power source structure to power the semiconductor device 800. The power structure can also include a plurality of interconnects and VIA contacts.

The interconnects in conductive interconnection structures (812, 816) and conductive structures (814, 818) can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. The conductive interconnection structures (812, 816) and conductive structures (814,818) can be formed by a plurality of processes including, but not limited to, photolithography, dry/wet etch, thin film deposition, thermal growth, implantation, chemical mechanical polishing (CMP), and any other suitable processes. The dielectric structure, e.g., ILD layers, can be deposited using one or more thin film deposition processes, including, but not limited to, chemical vapor deposition (CVD), physical vapor deposition (PVD), atomic layer deposition (ALD), sputtering, or any combination thereof. The conductive interconnection structures (812, 816) and conductive structures (814, 818) can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 8C illustrates a cross-section view of an example semiconductor device 850 with three semiconductor structures and one control structure. The semiconductor device 850 can include a first semiconductor structure 402, a second semiconductor structure 406, a third semiconductor structure 852, and a control structure 404. The first semiconductor structure 402, the second semiconductor structure 406 and the third semiconductor structure 852 can be integrated on the same side of the first control structure 404.

The first semiconductor structure 402, the second semiconductor structure 406 and the control structure 404 can have the same or substantially similar structure as those described above in FIG. 8B. In some implementations, the third semiconductor structure 852 has a first circuitry 858 and a fifth bonding layer 860 in its first side 862. The first control structure 404 includes the first peripheral circuitry 410, the second peripheral circuitry 412 and a third peripheral circuitry 416 in the first side 726 of the first control structure 404. The first peripheral circuitry 410 is connected to a first memory array of the first semiconductor structure 402. The second peripheral circuitry 412 is connected to a second memory array of the second semiconductor structure 406. The third peripheral circuitry 416 is connected to a third memory array of the third semiconductor structure 852.

In some implementations, a third conductive interconnection structure 864 is formed on a second side 866 of the third semiconductor structure 852. The third conductive interconnection structure 864 can be connected to the first circuitry 858 of the third semiconductor structure 852. The first circuitry 858 of the third semiconductor structure 852 can be connected to the third peripheral circuitry 416 at least by a fourth conductive structure 854 coupled between the third conductive interconnection structure 864 and the third peripheral circuitry 416. The fourth conductive structure 854 can extend through all three semiconductor structures (402, 406, 852) and corresponding interface bonding layers to connect to the third peripheral circuitry 416 of the control structure 404.

In some implementations, the conductive structures (814, 818, 854) are through-silicon-vias (TSV) or through-silicon-contact (TSC). The conductive interconnection structures (812, 816, 864) and the conductive structures (814, 818, 854) can work together to connect (i) the first peripheral circuitry 410 and the first circuitry 712 of the first semiconductor structure 402, (ii) the second peripheral circuitry 412 and the first circuitry 714 of the second semiconductor structure 406, and (iii) the third peripheral circuitry 416 and the first circuitry 858 of the third semiconductor structure 852. In some implementations, the first circuitry 712 of the first semiconductor structure 402, the first circuitry 714 of the second semiconductor structure 406 and the first circuitry 858 of the third semiconductor structure 852 are connected to each other in the control structure 404. All four structures (402, 404, 406 and 852) function together to manage and control memory arrays.

In some implementations, the second semiconductor structure 406 includes a sixth bonding layer 868 which is in contact with the fifth bonding layer 860 of the third semiconductor structure 852. In some implementations, the fifth bonding layer 860 and the sixth bonding layer 868 utilizes direct bonding techniques, e.g., as described above in FIG. 7A.

In some implementations, the fifth bonding layer 860 and the sixth bonding layer 868 are bonded together by hybrid bonding, e.g., as described above in FIG. 7C. A hybrid bonding can include a combination of metal-to-metal bonding and a direct bonding. For example, the fifth bonding layer 860 of the third semiconductor structure 852 can include one or more fifth conductive contacts (not shown) isolated by a dielectric material. The sixth bonding layer 868 of the second semiconductor structure 406 can include one or more sixth conductive contacts isolated by a same or different dielectric material. At least one of the fifth conductive contacts can be in contact with a corresponding one of the sixth conductive contacts. With hybrid bonding, the fourth conductive structure 854 can extend through part of the third semiconductor structure 852 to a bonding contact, e.g., a fifth conductive contact of the fifth bonding layer 860.

In some implementations, a hybrid bonding technique is utilized for bonding between any two adjacent structures, e.g., between the control structure 404 and the first semiconductor structure 402, between the first semiconductor structure 402 and the second semiconductor structure 406, and between the second semiconductor structure 406 and the third semiconductor structure 852. In some implementations, a direct bonding technique is utilized for bonding between any two adjacent structures. In some implementations, both hybrid bonding technique and direct bonding technique are utilized for the semiconductor device 850. For example, the hybrid bonding technique can be utilized for bonding between the control structure 404 and the first semiconductor structure 402, while the direct bonding technique can be utilized for bonding between the first semiconductor structure 402 and the second semiconductor structure 406, and between the second semiconductor structure 406 and the third semiconductor structure 852.

In some implementations, the conductive interconnection structures (812, 816, 864) include a plurality of interconnects (also referred to herein as “contacts”), including lateral interconnect lines and VIA contacts. The conductive interconnection structures (812, 816, 864) can further include one or more interlay dielectric (ILD) layers in which the interconnect lines and via contacts can form. That is, the conductive interconnection structures (812, 816, 864) can include interconnect lines and via contacts in multiple ILD layers. In some implementations, the conductive interconnection structures (812, 816, 864) further include a power source structure to power the semiconductor device 800. The power structure can also include a plurality of interconnects and VIA contacts.

The interconnects in conductive interconnection structures (812, 816, 864) and conductive structures (814, 818, 854) can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. The conductive interconnection structures (812, 816, 864) and conductive structures (814, 818, 854) can be formed by a plurality of processes including, but not limited to, photolithography, dry/wet etch, thin film deposition, thermal growth, implantation, chemical mechanical polishing (CMP), and any other suitable processes. The dielectric structure, e.g., ILD layers, can be deposited using one or more thin film deposition processes, including, but not limited to, chemical vapor deposition (CVD), physical vapor deposition (PVD), atomic layer deposition (ALD), sputtering, or any combination thereof. The conductive interconnection structures (812, 816, 864) and conductive structures (814, 818, 854) can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

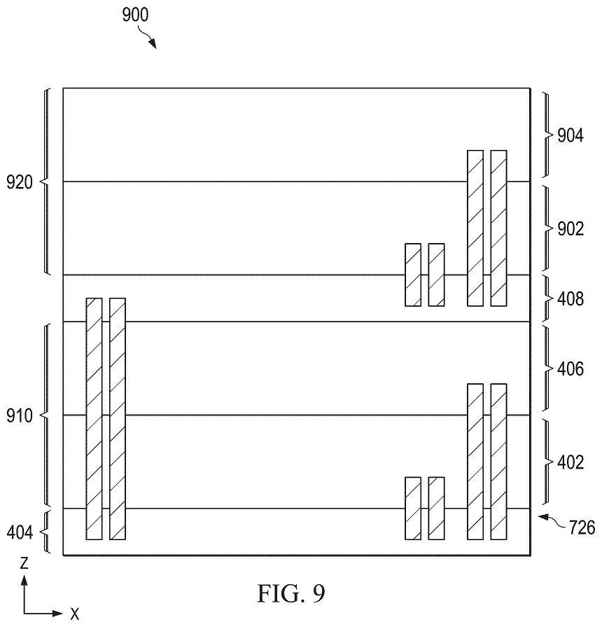

FIG. 9 illustrates a simplified cross-section view of an example semiconductor device 900. The semiconductor device 900 includes one or more control structures. For illustration, two control structures, 404, 408 are shown in FIG. 9. The semiconductor device 900 includes a first plurality 910 of semiconductor structures, which includes the first semiconductor structure 402 and the second semiconductor structure 406. The semiconductor device 900 also includes a second plurality 920 of semiconductor structures, e.g., 902 and 904. The semiconductor structure 902, 904 can be similar to, or same as, the semiconductor structure 402, 406. The first plurality 910 of semiconductor structures is stacked on the first side 726 of the first control structure 404. The first plurality 910 of semiconductor structures and the second plurality 920 of semiconductor structures 406 are stacked on opposite sides of the second control structure 408 along the Z direction. The bonding techniques between any two structures can involve direct bonding or hybrid bonding, e.g., as described above in FIGS. 7A and 7C.

In some implementations, the control structures 404, 408 are connected together to an external device. For example, the external device can include a power source and/or control units.

In some implementations, the first control structure 404 includes a first set of second circuitries. The first set can include one or more second circuitries. The first set of second circuitries are respectively coupled to the first circuitries in the first plurality 910 of semiconductor structures. Likewise, the second control structure 408 includes a second set of second circuitries. The second set can also include one or more second circuitries. The second set of second circuitries are respectively coupled to the first circuitries in the second plurality 920 of semiconductor structures.

Although not shown, it is understood that the semiconductor device 900 can include additional semiconductor structures and additional control structures. In some implementations, semiconductor device 900 includes a third plurality of semiconductor structures and a third control structure. The third plurality of semiconductor structure includes one or more semiconductor structures. Each semiconductor structure includes a memory array and a first circuitry. The third control structure includes one or more peripherical circuitries or second circuitries. The control circuitries in the third control structure can be respectively connected to the memory arrays and/or first circuitries in third plurality of semiconductor structures. The third plurality of semiconductor structure and the second plurality of semiconductor structure can be bonded on opposite sides of the third control structure.

In some implementations, the semiconductor device 900 includes conductive interconnection structures and/or conductive contacts which function together to connect the first circuitries with corresponding peripheral circuitries of corresponding control structures. All semiconductor structures and control structures function together to manage and control memory arrays in the semiconductor structures.

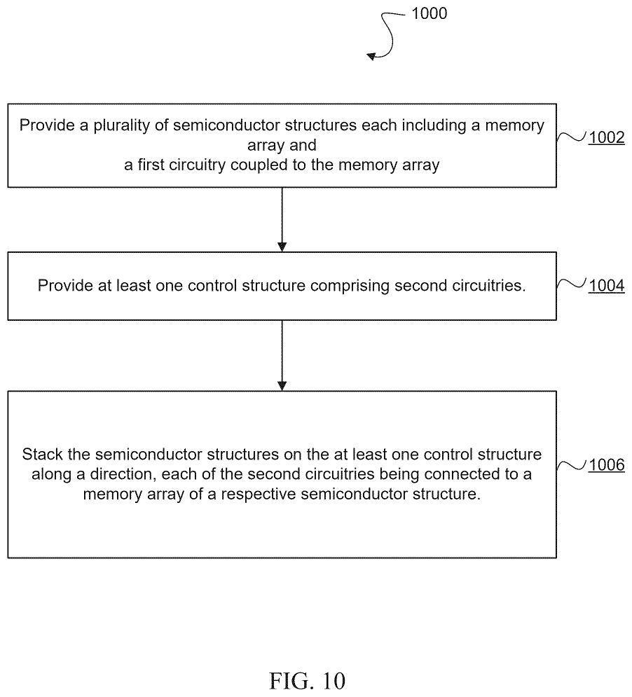

FIG. 10 is a flowchart chart of an example process 1000 for forming a semiconductor device. At step 1002, multiple semiconductor structures are provided. Each of the semiconductor structures includes a memory array and a first circuitry coupled to the memory array. Each semiconductor structure includes one or two bonding layers. The semiconductor structure can be, e.g., the semiconductor structure 402, 406 of FIGS. 4 and 7A-8C, the semiconductor structure 500 of FIG. 5A, the semiconductor structure 852 of FIG. 8C, or the semiconductor structure 902, 904 of FIG. 9. The memory array can be, e.g., the memory subarray 208 of FIGS. 2-3, or the memory array 502 of FIGS. 5A-5C and 7A-8C. The first circuitry can be, e.g., the first circuitry 310 of FIG. 3, the first circuitry 504 of FIGS. 5A, the first circuitry 712, 714 of FIGS. 7B-7C and 8C, or the first circuitry 858 of FIG. 8C. The bonding layers of the semiconductor structures can be, e.g., the bonding layers 530, 540 of FIG. 5A, the bonding layers 422, 424 of FIGS. 4, 7A-7C, the bonding layers 804, 806, 808 of FIGS. 8A-8C, or the bonding layers 860, 868 of FIG. 8C.

At step 1004, at least one control structure is provided, which can include second circuitries. The control structure can be, e.g., the control structure 404 of FIGS. 4 and 7A-9, or the control structure 600 of FIG. 6. Second circuitries can be, e.g., the first peripheral circuitry 410 and the second peripheral circuitry 412 of FIGS. 4, 7B-7C and 8C, the third peripheral circuitry 416 of FIG. 8C, or the second circuitry 612 of FIG. 6.

At step 1006, the semiconductor structures are stacked on the at least one control structure along a direction. Each of the second circuitries is connected to a memory array of a respective semiconductor structure. In some implementations, semiconductor structures are stacked on opposite sides of a control structure of the at least one control structure along the direction. In some implementations, semiconductor structures are stacked on a same side of a control structure of the at least one control structure along the direction.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for case of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
semiconductor structures, each of the semiconductor structures comprising a memory array and a first circuitry coupled to the memory array; and
at least one control structure comprising second circuitries for the semiconductor structures, wherein each of the second circuitries is coupled to a memory array of a respective semiconductor structure of the semiconductor structures,
wherein the semiconductor structures and the at least one control structure are stacked together along a direction.

2. The semiconductor device of claim 1, wherein the at least one control structure comprises two or more control structures that are connected together to an external device.

3. The semiconductor device of claim 1, wherein the semiconductor structures comprise a first semiconductor structure having a first bonding layer and a second semiconductor structure having a second bonding layer,
wherein the at least one control structure comprises a control structure having a third bonding layer and a fourth bonding layer, the third bonding layer being in a first side of the control structure, the fourth bonding layer being in a second side of the control structure that is opposite to the first side of the control structure along the direction, and
wherein the first semiconductor structure and the second semiconductor structure are integrated on opposite sides of the control structure, with the first bonding layer being in contact with the third bonding layer and the second bonding layer being in contact with the fourth bonding layer.

4. The semiconductor device of claim 3, wherein a first circuitry of the first semiconductor structure and the first bonding layer are in a first side of the first semiconductor structure,
wherein a first circuitry of the second semiconductor structure and the second bonding layer are in a first side of the second semiconductor structure, and
wherein the control structure comprises a first peripheral circuitry and a second peripheral circuitry in the first side of the control structure, and the first peripheral circuitry is connected to a first memory array of the first semiconductor structure and the second peripheral circuitry is connected to a second memory array of the second semiconductor structure.

5. The semiconductor device of claim 4, further comprising:
a first conductive interconnection structure on the second side of the control structure, wherein the first peripheral circuitry and the second peripheral circuitry are respectively connected to the first conductive interconnection structure; and
a second conductive interconnection structure on a second side of the second semiconductor structure that is opposite to the first side of the second semiconductor structure along the direction,
wherein the first circuitry of the first semiconductor structure is connected to the first peripheral circuitry at least by a first conductive structure coupled between the first circuitry of the first semiconductor structure and the first conductive interconnection structure, the first conductive structure extending through the first bonding layer, the third bonding layer, and the control structure along the direction, and
wherein the first circuitry of the second semiconductor structure is connected to the second peripheral circuitry at least by a second conductive structure coupled between the first circuitry of the second semiconductor structure and the second conductive interconnection structure and a third conductive structure coupled between the second conductive interconnection structure and the first conductive interconnection structure, the second conductive structure extending at least partially through the second semiconductor structure along the direction, the third conductive structure extending through the second semiconductor structure, the second bonding layer, and the fourth bonding layer along the direction.

6. The semiconductor devices of claim 4, wherein the first bonding layer comprises one or more first conductive contacts isolated by a first dielectric material, the second bonding layer comprises one or more second conductive contacts isolated by a second dielectric material, the third bonding layer comprises one or more third conductive contacts isolated by a third dielectric material, and the fourth bonding layer comprises one or more fourth conductive contacts isolated by a fourth dielectric material, and
wherein at least one of the one or more first conductive contacts is in contact with a corresponding one of the one or more third conductive contacts, and at least one of the one or more second conductive contacts is in contact with a corresponding one of the one or more fourth conductive contacts.

7. The semiconductor device of claim 6, further comprising:
a conductive interconnection structure on a second side of the first semiconductor structure that is opposite to the first side of the first semiconductor structure along the direction,
wherein the first peripheral circuitry is connected to the conductive interconnection structure by a first conductive structure extending in the first semiconductor structure, a first conductive contact of the one or more first conductive contacts, and a corresponding third conductive contact of the one or more third conductive contacts that is in contact with the first conductive contact,
wherein the first circuitry of the first semiconductor structure is connected to the first peripheral circuitry by one or more other first conductive contacts being in contact with corresponding one or more other third conductive contacts, and
wherein the first circuitry of the second semiconductor structure is connected to the second peripheral circuitry by the at least one of the one or more second conductive contacts, the corresponding one of the one or more fourth conductive contacts, and a second conductive structure at least partially extending through the control structure.

8. The semiconductor device of claim 1, wherein the at least one control structure comprises a first control structure having a first bonding layer,
wherein the semiconductor structures comprise a first semiconductor structure and a second semiconductor structure that are stacked on a first side of the first control structure along the direction,
wherein the first semiconductor structure comprises a second bonding layer in a first side of the first semiconductor structure and a third bonding layer in a second side of the first semiconductor structure that is opposite to the first side of the first semiconductor structure,
wherein the second semiconductor structure comprises a fourth bonding layer, and
wherein the first semiconductor structure is stacked on the first control structure with the first bonding layer being in contact with the second bonding layer, and the second semiconductor structure is stacked on the first semiconductor structure with the fourth bonding layer being in contact with the third bonding layer.

9. The semiconductor device of claim 8, wherein a first circuitry of the first semiconductor structure and the second bonding layer are in the first side of the first semiconductor structure,
wherein a first circuitry of the second semiconductor structure and the fourth bonding layer are in a first side of the second semiconductor structure, and
wherein the first control structure comprises a first peripheral circuitry and a second peripheral circuitry in the first side of the first control structure, and wherein the first peripheral circuitry is connected to a first memory array of the first semiconductor structure, and the second peripheral circuitry is connected to a second memory array of the second semiconductor structure.

10. The semiconductor device of claim 9, further comprising:
a first conductive interconnection structure on the second side of the first semiconductor structure, the first conductive interconnection structure being connected to the first circuitry of the first semiconductor structure; and
a second conductive interconnection structure on a second side of the second semiconductor structure that is opposite to the first side of the second semiconductor structure along the direction, the second conductive interconnection structure being connected to the first circuitry of the second semiconductor structure,
wherein the first circuitry of the first semiconductor structure is connected to the first peripheral circuitry at least by a first conductive structure coupled between the first conductive interconnection structure and the first peripheral circuitry, the first conductive structure extending at least partially through the first semiconductor structure along the direction, and
wherein the first circuitry of the second semiconductor structure is connected to the second peripheral circuitry at least by a second conductive structure coupled between the second conductive interconnection structure and the second peripheral circuitry, the second conductive structure extending through at least partially through the second semiconductor structure and at least partially through the first semiconductor structure along the direction.

11. The semiconductor device of claim 8, wherein the at least one control structure comprises a second control structure, and wherein the semiconductor structures comprise a first plurality of semiconductor structures including the first semiconductor structure and the second semiconductor structure and a second plurality of semiconductor structures,
wherein the first plurality of semiconductor structures are stacked on the first side of the first control structure, and
wherein the first plurality of semiconductor structures and the second semiconductor structures are stacked on opposite sides of the second control structure along the direction.

12. The semiconductor device of claim 11, wherein the first control structure comprises a first plurality of second circuitries respectively coupled to first circuitries in the first plurality of semiconductor structures, and
wherein the second control structure comprises a second plurality of second circuitries respectively coupled to first circuitries in the second plurality of semiconductor structures.

13. The semiconductor device of claim 1, wherein a memory cell of the memory array comprises a transistor and a capacitor,
wherein the transistor comprises a gate as at least part of a word line, a first terminal coupled to a bit line, and a second terminal coupled to the capacitor, and
wherein the bit line and the capacitor are on a same side of the word line.

14. The semiconductor device of claim 1, wherein the first circuitry comprises at least one of a sense amplifier coupled to a corresponding bit line or a word line driver coupled to a corresponding word line, and
wherein the second circuitry comprises an input-output (I/O) circuitry configured to communicate with one or more external devices.

15. A semiconductor device, comprising:
semiconductor structures, each of the semiconductor structures comprising a memory array and a first circuitry coupled to the memory array; and
at least one control structure comprising second circuitries for the semiconductor structures,
wherein the semiconductor structures and the at least one control structure are stacked together along a direction, and
wherein a memory cell of the memory array comprises a transistor and a capacitor, wherein the transistor comprises a gate as at least part of a word line, a first terminal coupled to a bit line, and a second terminal coupled to the capacitor, and wherein the bit line and the capacitor are on a same side of the word line.

16. The semiconductor device of claim 15, wherein the semiconductor structures comprise a first semiconductor structure having a first bonding layer and a second semiconductor structure having a second bonding layer, wherein the at least one control structure comprises a control structure having a third bonding layer and a fourth bonding layer, the third bonding layer being in a first side of the control structure, the fourth bonding layer being in a second side of the control structure that is opposite to the first side of the control structure along the direction, and wherein the first semiconductor structure and the second semiconductor structure are integrated on opposite sides of the control structure, with the first bonding layer being in contact with the third bonding layer and the second bonding layer being in contact with the fourth bonding layer, and
wherein a first circuitry of the first semiconductor structure and the first bonding layer are in a first side of the first semiconductor structure, wherein a first circuitry of the second semiconductor structure and the second bonding layer are in a first side of the second semiconductor structure, and wherein the control structure comprises a first peripheral circuitry and a second peripheral circuitry in the first side of the control structure, and the first peripheral circuitry is connected to a first memory array of the first semiconductor structure and the second peripheral circuitry is connected to a second memory array of the second semiconductor structure.

17. The semiconductor devices of claim 16,
wherein the first bonding layer comprises one or more first conductive contacts isolated by a first dielectric material, the second bonding layer comprises one or more second conductive contacts isolated by a second dielectric material, the third bonding layer comprises one or more third conductive contacts isolated by a third dielectric material, and the fourth bonding layer comprises one or more fourth conductive contacts isolated by a fourth dielectric material, and
wherein at least one of the one or more first conductive contacts is in contact with a corresponding one of the one or more third conductive contacts, and at least one of the one or more second conductive contacts is in contact with a corresponding one of the one or more fourth conductive contacts.

18. The semiconductor device of claim 15, wherein the at least one control structure comprises a first control structure having a first bonding layer, wherein the semiconductor structures comprise a first semiconductor structure and a second semiconductor structure that are stacked on a first side of the first control structure along the direction, wherein the first semiconductor structure comprises a second bonding layer in a first side of the first semiconductor structure and a third bonding layer in a second side of the first semiconductor structure that is opposite to the first side of the first semiconductor structure, wherein the second semiconductor structure comprises a fourth bonding layer, and wherein the first semiconductor structure is stacked on the first control structure with the first bonding layer being in contact with the second bonding layer, and the second semiconductor structure is stacked on the first semiconductor structure with the fourth bonding layer being in contact with the third bonding layer, and
wherein a first circuitry of the first semiconductor structure and the second bonding layer are in the first side of the first semiconductor structure, wherein a first circuitry of the second semiconductor structure and the fourth bonding layer are in a first side of the second semiconductor structure, and wherein the first control structure comprises a first peripheral circuitry and a second peripheral circuitry in the first side of the first control structure, and wherein the first peripheral circuitry is connected to a first memory array of the first semiconductor structure, and the second peripheral circuitry is connected to a second memory array of the second semiconductor structure.

19. A method for forming a semiconductor device, the method comprising:
providing semiconductor structures, each of the semiconductor structures comprising a memory array and a first circuitry coupled to the memory array;
providing at least one control structure comprising second circuitries; and
stacking the semiconductor structures on the at least one control structure along a direction and connecting each of the second circuitries to a memory array of a respective semiconductor structure of the semiconductor structures.

20. The method of claim 19, wherein stacking the semiconductor structures on the at least one control structure comprises at least one of:
stacking semiconductor structures on opposite sides of a control structure of the at least one control structure along the direction, or
stacking semiconductor structures on a same side of a control structure of the at least one control structure along the direction.
